(19) United States
(12) Patent Application Publication
(10) Pub. No.: US 2007/0107775 A1
(43) Pub. Date: May 17, 2007

(54) Solar cell and manufacturing method of the same

(75) Inventors: Jae-Man Choi, Suwon-si (KR); Ji-Won Lee, Suwon-si (KR); Wha-Sup Lee, Suwon-si (KR); Kwang-Soon Ahn, Suwon-si (KR); Byong-Cheol Shin, Suwon-si (KR); Joung-Won Park, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd., Suwon-si (KR)

(21) Appl. No.: 11/593,087

(22) Filed: Nov. 6, 2006

(30) Foreign Application Priority Data
Nov. 11, 2005 (KR) 10-2005-0107932

(51) Int. Cl. H01L 31/00

(52) U.S. Cl. 136/263

(57) ABSTRACT

A solar cell includes a substrate, an electrode formed on the substrate, and a light absorption layer formed on the electrode. A contact area enlargement region is formed between the electrode and the light absorption layer. The solar cell is formed by forming an electrode with a contact area enlargement region; and forming a light absorption layer on the electrode.

### CROSS-REFERENCE TO RELATED APPLICATION

This application claims priority to and the benefit of Korean Patent Application No. 2005-107932 filed in the Korean Intellectual Property Office on Nov. 11, 2005, the entire disclosure of which is incorporated herein by reference.

### BACKGROUND OF THE INVENTION

1. Field of the Invention

Aspects of the present invention relate to a solar cell and a manufacturing method thereof, and in particular, to a solar cell with high energy efficiency, and a method of manufacturing the solar cell.

2. Description of the Related Art

Generally, a solar cell generates electrical energy using solar energy, an unlimited energy source, in an environmentally friendly way. Typical solar cells include silicon solar cells, dye-sensitized solar cells, etc.

A solar cell typically has a first electrode having a dye-adsorbed porous film formed thereon, and a second electrode facing the first electrode with a predetermined distance there between. The dye-sensitized solar cell is produced with simplified processing steps and a lower production cost compared to the silicon solar cell. Furthermore, since the first and second electrodes in the dye-sensitized solar cell are formed with a transparent material, the dye-sensitized solar cell may be used in constructing an outer wall for buildings or greenhouses.

However, the dye-sensitized solar cell has a lower photoelectric conversion efficiency than the silicon solar cell, and it is limited in the practical usage thereof. In order to increase the photoelectric conversion efficiency, it has been proposed that the reflectivity of the second electrode should be increased or that light-scattering particles should be used, but the proposed methods are limited in the extent to which they can increase the photoelectric conversion efficiency of the dye-sensitized solar cell. In this regard, it is desirable to develop a new technology for enhancing the photoelectric conversion efficiency of the dye-sensitized solar cell as well as of other kinds of solar cells.

### SUMMARY OF THE INVENTION

Aspects of the present invention provide a solar cell with enhanced photoelectric conversion efficiency, and a method of manufacturing the solar cell.

According to one aspect of the present invention, the solar cell includes a substrate, an electrode formed on the substrate, and a light absorption layer formed on the electrode. A contact area enlargement region is formed between the electrode and the light absorption layer.

According to an aspect of the present invention, the contact area enlargement region may be formed with prominent and depressed portions. In particular, the contact area enlargement region may be formed by forming prominent and depressed portions on the substrate and forming the electrode on the substrate such that the electrode conforms to the prominent and depressed portions of the substrate and forming the light absorption layer on the electrode.

According to an aspect of the present invention, the surface roughness of the electrode may have a root mean square of 10 nm-3000 nm. The roughness of the surface of the substrate with the electrode may have a root mean square of 10 nm-3000 n. In particular, the roughness of the surface of the substrate before the electrode is formed thereon may have a root mean square of 10 nm-3000 n.

According to an aspect of the present invention, prominent and depressed portions may be formed in the shape of steps, meshes, scratches, scars, or beds.

According to another aspect of the present invention, a solar cell includes first and second substrates facing each other; a first electrode formed on the first substrate; a light absorption layer formed on the first electrode; and a second electrode formed on the second substrate, wherein the surface roughness of the first electrode is greater than the surface roughness of the second electrode. That is, the surface roughness of the first electrode may have a root mean square that is greater than that of the second electrode.

According to an aspect of the present invention, a method of manufacturing a solar cell includes forming an electrode with a contact area enlargement region, and forming a light absorption layer on the electrode.

According to an aspect of the present invention, in forming an electrode with a contact area enlargement region, the electrode may be formed on a substrate with prominent and depressed portions. The prominent and depressed portions of the substrate may be formed through mechanical etching or chemical etching. The mechanical etching may be selected from sandblasting, scratching, and plasma etching, and the chemical etching may be performed with a solution selected from nitric acid, hydrochloric acid, hydrofluoric acid and a mixture thereof.

According to another aspect of the present invention, a method of manufacturing a substrate/electrode/light absorption layer assembly of a solar cell comprises etching a substrate through mechanical or chemical etching to form prominent and depressed portions on a surface thereof; forming an electrode on the surface of the substrate such that a surface of the electrode has prominent and depressed portions conforming to the prominent and depressed portions of the surface of the substrate; and forming a light absorption layer on the electrode.

According to another aspect of the present invention, a method of manufacturing an electrode/light absorption layer assembly of a solar cell comprises forming an electrode on a surface of a substrate and controlling processing conditions of the forming such that a root mean square of roughness of a surface of the electrode is 10 nm-3000 nm; and forming a light absorption layer on the electrode.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a sectional view of a solar cell according to an embodiment of the present invention;

FIG. 2 is an atomic force microscope (AFM) image of a surface of a first electrode for a solar cell according to the embodiment of FIG. 1, wherein the electrode has prominent and depressed portions; and

FIG. 3 is a sectional view of a solar cell according to another embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

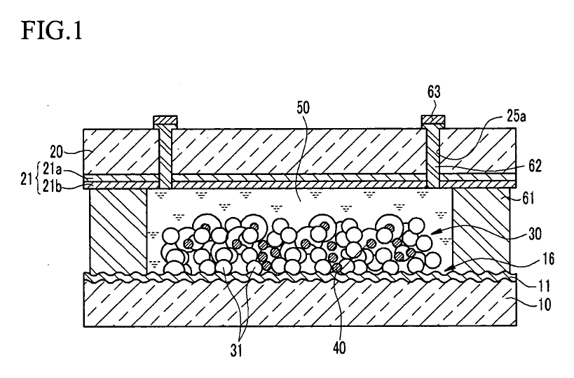

FIG. 1 is a sectional view of a solar cell according to an embodiment of the present invention.

As shown in FIG. 1, the solar cell according to aspects of the present embodiment includes a first substrate 10 with a first electrode 11 and a porous film 30 including an adsorbed dye 40, a second substrate 20 facing the first substrate 10 with a predetermined distance therebetween and having a second electrode 21, and an electrolyte 50 disposed between the first and second substrates 10 and 20. The dye-adsorbed porous film 30 has a role of generating electrons upon receipt of the light incident thereto and delivering the electrons to the first electrode 11. The porous film 30 and the adsorbed dye 40 may be collectively referred to as a light absorption layer. The first substrate 10 having the first electrode 11 and the light absorption layer may be collectively referred to as the substrate/electrode/light absorption layer assembly. A separate case (not shown) may be provided external to the first and second substrates 10 and 20.

In this embodiment, the first substrate 10, which functions as a support for the first electrode 11, is formed with a transparent material that allows light to pass therethrough. The first substrate 10 may be formed with glass or plastic. The plastic may be selected from polyethylene terephthalate (PET), polyethylene naphthalate (PEN), polycarbonate (PC), polypropylene (PP), polyimide (PI), and triacetyl cellulose (TAC). The first substrate 10 is not limited to these materials, and other materials are possible.

The first electrode 11 provided on the first substrate 10 may be formed with indium tin oxide (ITO), fluorine tin oxide (FTO), antimony tin oxide (ATO), zinc oxide (ZO), tin oxide (TO), ZnO—Ga₂O₃, or ZnO—Al₂O₃. The first electrode 11 is not limited to these materials, and other materials are possible. The first electrode 11 may be formed with a transparent material-based single layer structure, or a laminated layer structure.

In this embodiment, a contact area enlargement region 16 is formed between the first electrode 11 and the porous film 30. The contact area enlargement region 16 is made by forming prominent and depressed portions at the first electrode 11. More specifically, prominent and depressed portions are formed at a surface of the first substrate 10, and the first electrode 11 is formed on that rugged surface of the first substrate 10. The first electrode 11 conforms to the surface of the first substrate 10 such that the surface of the first electrode 11 also has the prominent and depressed portions.

The root mean square (Rms) of the surface roughness at the surface of the first substrate 10 with the prominent and depressed portions may be 10 nm-3000 nm. Since the first electrode 11 conforms to the surface of the first substrate 10, the Rms of the surface roughness at the surface of the first electrode 11 with the porous film 30 may also be 10 nm-3000 nm. Typically, but not necessarily, the surface roughness of the first substrate 10 may be determined before the first electrode is deposited thereon, or in the absence of the first electrode and the surface roughness of the first electrode may be measured before the light absorption layer is formed thereon, or in the absence of the light absorption layer. However, the surface roughness may also be determined under other conditions.

It is difficult in practice to form prominent and depressed portions to provide an Rms of the surface roughness of less than 10 nm. On the other hand, when the Rms of the surface roughness exceeds 3000 nm, light transmittance is lowered and the energy efficiency deteriorates to such an extent as to offset the efficiency enhancement gained by the increase in the contact area. Furthermore, if the Rms of the surface roughness does not exceed 3000 nm, the electron transfer may be performed more effectively.

The prominent and depressed portions formed at the first substrate 10 and the first electrode 11 to function as the contact area enlargement region 16 may be structured such that they enlarge the contact area between the first electrode 11 and the porous film 30. The prominent and depressed portions may be formed in the shape of steps, meshes, scratches, scars, beds or other shapes.

The porous film 30 is placed or formed on the first electrode 11. The porous film 30 includes metallic oxide particles 31 having a nanometer-level mean particle diameter. The metallic oxide particles 31 may comprise titanium oxide, zinc oxide, tin oxide, strontium oxide, indium oxide, iridium oxide, lanthanum oxide, vanadium oxide, molybdenum oxide, tungsten oxide, niobium oxide, magnesium oxide, aluminum oxide, yttrium oxide, scandium oxide, samarium oxide, gallium oxide, or strontium titanium oxide. For instance, the metallic oxide particles 31 of the porous film 30 may comprise titanium oxide TiO₂. The metallic oxide particles 31 are not limited to these materials, and other materials are possible.

As a non-limiting example, the metallic oxide particles 31 with a nanometer-level mean particle diameter may be uniformly distributed with suitable porosity and surface roughness to form the porous film 30.

In order to enhance the performance characteristics of the porous film 30, a polymer (not shown), conductive micro particles (not shown), and light-scattering particles (not shown) may be added to the porous film 30.

The polymer may be added to the porous film 30 to increase the porosity, diffusivity, and viscosity of the porous film 30, thereby enhancing the film formation and adhesion thereof. The polymer may be selected from polyethylene glycol (PEG), polyethylene oxide (PEO), polyvinyl alcohol (PVA), and polyvinyl pyrrolidone (PVP). The polymer is not limited to these materials, and other materials are possible. The molecular weight of the polymer may be selected taking into account the method and conditions of formation of the porous film 30.

Conductive micro particles may be added to the porous film 30 to enhance the mobility of the excited electrons. For instance, the conductive micro particles may comprise indium tin oxide. The conductive micro particles are not limited to these materials, and other materials are possible.

Light-scattering particles may be added to the porous film 30 to extend the optical path within the solar cell to enhance the photoelectric conversion efficiency thereof. The light-scattering particles may be formed with the same material as the metallic oxide particles 31 for the porous film 30. The light scattering particles are not limited to these materials, and other materials are possible. The light-scattering particles preferably have a mean particle diameter of 100 nm or more to effectively scatter the light.

The dye 40 is adsorbed onto the surface of the metallic oxide particles 31 of the porous film 30 to absorb external light and excite electrons. The dye 40 may be formed with a metal complex containing aluminum (Al), platinum (Pt), palladium (Pd), europium (Eu), lead (Pb), or iridium (Ir), or with a ruthenium (Ru) complex. Ruthenium belongs to the platinum group, and a ruthenium-containing dye is commonly used as an organic metal complex compound. The metal complex is not limited to these materials, and other materials are possible.

Furthermore, a dye may be selected that is capable of improving the absorption of long wavelength visible rays to enhance the photoelectric conversion efficiency and/or that is capable of easily emitting electrons. For example, an organic dye may be used. The organic dye may be used independently or in association with a metal complex such as, for example, the ruthenium complex mentioned above. The organic dye may be selected from coumarin, porphyrin, xanthene, riboflavin, and triphenylmethane. The organic dye is not limited to these materials, and other materials are possible.

The second substrate 20, which faces the first substrate 10 in the assembled solar cell, supports the second electrode 21, and is formed with a transparent material. The second substrate 20 may be formed with glass or plastic. The plastic may be selected from polyethylene terephthalate, polyethylene naphthalate, polycarbonate, polypropylene, polyimide, and triacetyl cellulose. The second substrate 21 is not limited to these materials, and other materials are possible.

The second electrode 21 formed on the second substrate 20 faces the first electrode 11 and includes a transparent electrode 21a and a catalyst electrode 21b.

The transparent electrode 21a may be formed with a transparent material such as indium tin oxide, fluorine tin oxide, antimony tin oxide, zinc oxide, tin oxide, ZnO—Ga₂O₃, and ZnO-Al₂O₃. The transparent electrode 21a is not limited to these materials, and other materials are possible. The transparent electrode 21a may be formed with a single layer structure based on a transparent material, or with a laminated layer structure. The catalyst electrode 21b activates the redox couple, and may be formed with platinum, ruthenium, palladium, iridium, rhodium, osmium, carbon, WO₃, or TiO₂. The catalyst electrode 21b is not limited to these materials, and other materials are possible.

In this embodiment, the prominent and depressed portions functioning as the contact area enlargement region are not formed at the second electrode 21, and hence the surface roughness of the first electrode 11 is greater than the surface roughness of the second electrode 21. That is, the Rms of the surface roughness of the first electrode 11 is established to be greater than the Rms of the surface roughness of the second electrode 21. The Rms of the surface roughness of the second electrode 21 may be less than 10 nm.

The first and second substrates 10 and 20 are attached to each other using an adhesive 61. An electrolyte 50 is injected into the interior between the first and second electrodes 11 and 21 through holes 25a formed at the second substrate 20 and the second electrode 21. The electrolyte 50 is uniformly diffused into the porous film 30. The electrolyte 50 may comprise a solution including iodide and triiodide. The electrolyte receives and transfers electrons from the second electrode 21 to the dye 40 through reduction and oxidation. The holes 25a formed at the second substrate 20 and the second electrode 21 are sealed by an adhesive 62 and a cover glass 63.

The electrolyte 30 is not limited to a liquid electrolyte as described herein. For example, the electrolyte 30 may be in other forms, such as a gel or solid electrolyte, provided that the electrolyte is present between the first and second electrodes 11 and 21.

When external light such as sunlight hits the interior of the solar cell, photons are absorbed into the dye so that the dye is shifted from an inactive state to an excited state to thereby generate electron-hole pairs. The excited electrons migrate into the conduction bands of the metallic oxide particles 31 for the porous film 30, and flow to an external circuit (not shown) through the first electrode 11, and are then transferred to the second electrode 21. Meanwhile, as the iodide within the electrolyte 50 is oxidized into triiodide, the oxidized dye is reduced, and the triiodide is reacts with the electrons that have reached the second electrode 21 to be thereby reduced into iodide. The solar cell operates due to the migration of electrons.

Unlike the silicon solar cell, the dye-sensitized solar cell operates through a reaction at an interface, in particular, the interface between the porous film 30 of the light absorption layer and the electrode 11. Hence, it is beneficial to improve the characteristics of this interface. In this embodiment, a contact area enlargement region 16 is formed at the first substrate 10 and the first electrode 11 with prominent and depressed portions to thereby improve the contact characteristic thereof. The contact characteristic of the first electrode 11 and the porous film 30 is improved and the contact area therebetween is increased, thereby enhancing the mobility and speed of the electrons.

In this embodiment, the contact area enlargement region 16 is formed by creating prominent and depressed portions at the first substrate 10. The first electrode 11, formed on the first substrate 10 conforms to the first substrate so that the contact area enlargement region 16 is formed at the first electrode 11. In other words, the surface of the first electrode 11 has the same prominent and depressed portions that were on the surface of the first substrate. When the prominent and depressed portions are formed at the first substrate 10, processing is easily carried out, and the first electrode 11 is protected from possible processing failure, compared to the case in which the prominent and depressed portions are formed only at the first electrode 11 and not at the first substrate 10. When the prominent and depressed portions are directly formed at the first electrode 11 through etching, the first electrode 11 may suffer unwanted damage.

A method of manufacturing the above-structured solar cell will be now explained in detail.

A first substrate 10 made of a transparent material such as glass or plastic is provided. The plastic may be selected from polyethylene terephthalate, polyethylene naphthalate, polycarbonate, polypropylene, polyimide, and triacetyl cellulose. As noted above, the first substrate 10 is not limited to these materials, and other materials are possible.

Thereafter, prominent and depressed portions are formed at the first substrate 10 through mechanical etching or chemical etching. The formation of the prominent and depressed portions is not limited to these methods and other methods are possible. The mechanical etching may be carried out by sandblasting, scratching, or plasma etching, and the chemical etching may be performed by dipping the substrate in hydrofluoric acid, nitric acid, hydrochloric acid, or a mixed solution thereof. Consequently, the Rms of the surface roughness of the first substrate 10 comes to be in the range of 10 nm-3000 nm. The prominent and depressed portions may be in the shape of steps, meshes, scratches, scars, beds or other shapes.

A conductive layer is deposited onto a surface of the first substrate 10 with the prominent and depressed portions through sputtering, chemical vapor deposition (CVD), or spray pyrolysis deposition (SPD) to thereby form the first electrode 11. The formation of the first electrode 11 is not limited to these methods and other methods are possible. Because the first electrode 11 is relatively thin, the prominent and depressed portions that were formed at the first substrate 10 also appear at the surface of the first electrode 11. The resulting prominent and depressed portions of the first electrode 11 function as the contact area enlargement region 16. With the formation of the prominent and depressed portions, the Rms of the surface roughness of the first electrode 11 comes to be in the range of 10 nm-3000 nm. As stated above, the first electrode 11 may be formed with indium tin oxide, fluorine tin oxide, antimony tin oxide, zinc oxide, tin oxide, ZnO—Ga₂O₃, or ZnO—Al₂O₃ or other conductive materials. The first electrode 11 may be formed with a single layer structure based on a transparent material, or with a laminated layer structure.

A paste containing metallic oxide particles 31 is coated onto the first electrode 11 and heat-treated to thereby form a porous film 30. The paste may contain a polymer, light-scattering particles, and conductive micro particles in addition to the metallic oxide.

The coating of the paste may be performed in various ways including with a doctor blade, by screen printing, by spin coating, by spraying, and by wet coating. The method of coating may be selected to be compatible with a particular paste that is used. Alternatively, if a particular method of coating has already been selected, the paste may be selected to be compatible with the chosen method of coating.

If the paste contains a binder, the heat treatment o may be performed on the paste-coated electrode at 450-600° C. for 30 minutes. On the other hand, if the paste does not contain a binder, the heat treatment may be performed at 200° C. or less. However, different heating temperatures may be selected depending upon the composition of the paste, and heating temperature of the paste-coated electrode is not limited to the above examples.

Thereafter, the first substrate 10 with the first electrode 11 and the porous film 30 formed thereon is dipped in a alcoholic solution containing a dissolved dye for a predetermined period of time, thereby adsorbing the dye 40 into the porous film 30, thereby creating the light absorption layer.

The transparent electrode 21a and a catalyst electrode 21b are sequentially formed on the second substrate 20, which can be made of glass or plastic, for example, to thereby form a second electrode 21. The material for the second substrate 20 may be the same as that for the first substrate 10, and hence a detailed explanation thereof will be omitted. Similarly, the material for the transparent electrode 21a may be the same as that for the first electrode 11, and a detailed explanation thereof will be omitted.

The catalyst electrode 21b may be formed, for example, with platinum, ruthenium, rhodium, palladium, iridium, osmium, WO₃, TiO₂, or C. The formation of the catalyst electrode 21b may be accomplished, for example, through physical vapor deposition (such as electroplating, sputtering, and electron beam deposition), or wet coating (such as spin coating, dip coating, and flow coating). For example, when the catalyst electrode 21b is formed with platinum, H₂PtCl₆ may be dissolved in an organic solvent such as methanol, ethanol, and isopropyl alcohol (IPA) to make a solution, and the solution may be wet-coated onto the transparent electrode 21a and heat-treated at 400° C. under an air or oxygen atmosphere.

Thereafter, the first and second substrates 10 and 20 are arranged such that the first electrode 11 and the porous film 30 face the second electrode 21, and are attached to each other using an adhesive 61. The adhesive 61 may be formed with a thermoplastic polymer film (such as, for example, a resin provided by DuPont under the registered trademark SURLYN™), an epoxy resin, or an ultraviolet hardener. When the adhesive 61 is formed with a thermoplastic polymer film, the thermoplastic polymer film is placed between the first and second substrates 10 and 20, which are then thermally pressed, thereby attaching the first and second substrates 10 and 20 to each other.

An electrolyte 50 is injected into the interior between the first and second substrates 10 and 20 through holes 25a formed at the second substrate 20 and the second electrode 21, and the holes 25a are sealed using an adhesive 62 and a cover glass 63. (If a solid or other non-liquid form of electrolyte is used, the electrolyte is added before the first and second substrates 10 and 20 are joined.) In this way, a solar cell is completed. A separate case (not shown) may be provided external to the first and second substrates 10 and 20.

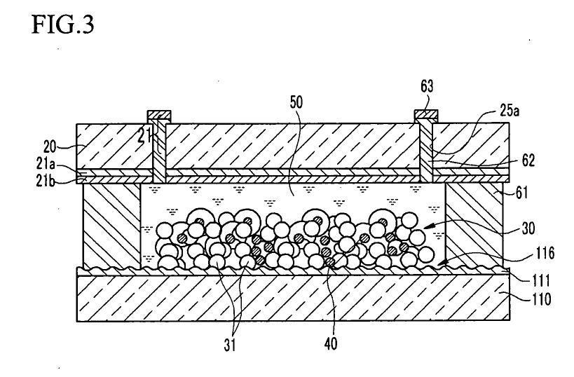

FIG. 3 is a sectional view of a solar cell according to another embodiment of the present invention. In this embodiment, like reference numerals are used for the same or similar structural components as those related to the previous embodiment, and only the different structures will now be explained. A method of manufacturing the solar cell is also substantially the same as that related to the previous embodiment, and hence a detailed explanation thereof will be omitted except for the formation of the first electrode.

In this embodiment, the first substrate 110 has a flat and smooth surface with no rugged portion. Prominent and depressed portions are formed at the first electrode 111 to create a contact area enlargement region 116. The first electrode 111 is formed through sputtering, chemical vapor deposition, or spray pyrolysis deposition, and the processing conditions are controlled such that the surface roughness of the first electrode 111 has an Rms of 10 nm-3000 nm.

A solar cell according to the present invention will be now specifically explained by way of examples. The examples are given only to illustrate the present invention, but not intended to limit the scope of the present invention.

### EXAMPLE 1

A first substrate was formed with soda-lime glass having a horizontal side of 2.2 cm, a vertical side of 2.2 cm, and a thickness of 1.1 mm. The first substrate was ultrasonically cleaned using distilled water. The clean first substrate was dipped in a hydrofluoric aqueous solution containing 49 wt % of hydrofluoric acid for 20 minutes, and etched. The first substrate was then ultrasonic-wave cleaned using distilled water, and an indium tin oxide layer with a thickness of 500 nm was deposited onto the first substrate through spray pyrolysis deposition, thereby forming a first electrode.

A paste containing TiO₂ particles with a mean particle diameter of 7 nm-50 nm was coated onto a surface of the first electrode with an area of 1 cm² through screen printing, and heat-treated at 450° C. for 30 minutes to thereby form a TiO₂-contained porous film with a thickness of 15 μm.

The first substrate with the porous film and the first electrode was dipped in a 0.3mM solution of ruthenium (4,4-dicarboxy-2,2′-bipyridine)₂(NCS)₂ for 24 hours, thereby adsorbing the dye into the porous film. The dye-adsorbed porous film was cleaned using ethanol.

A second substrate was formed with soda-lime glass having a horizontal side of 2.2 cm, a vertical side of 2.2 cm, and a thickness of 1.1 mm. The second substrate was ultrasonically cleaned using distilled water. Two holes were formed at the second substrate. Thereafter, an indium tin oxide layer with a thickness of 500 nm was deposited onto the second substrate through spray pyrolysis deposition to form a transparent electrode. A catalyst electrode based on platinum with a surface resistivity of 3 Ω/sq was formed on the transparent electrode through sputtering.

The first and second substrates were arranged such that the porous film formed on the first electrode faced the second electrode. A thermoplastic polymer film was disposed between the first and second substrates, and thermally pressed to thereby attach the first and second substrates to each other. An electrolyte was injected into the interior between the first and second substrates through the two holes formed at the second substrate and the second electrode, and the holes were sealed using a thermoplastic polymer film and a cover glass, thereby completing a solar cell. The electrolyte was based on a solution wherein 21.928 g of tetrapropylammonium iodide and 1.931 g of iodine (I₁₂) were dissolved in 100 ml of a mixed solvent of 80 vol % of ethylene carbonate and 20 vol % of acetonitrile.

### EXAMPLE 2

A solar cell was manufactured in the same way as in Example 1 except that the first substrate was etched for 40 minutes.

### EXAMPLE 3

A solar cell was manufactured in the same way as in Example 1 except that the first substrate was etched for 90 minutes.

### EXAMPLE 4

A solar cell was manufactured in the same way as in Example 1 except that the first substrate was etched for 150 minutes.

### EXAMPLE 5

A solar cell was manufactured in the same way as in Example 1 except that the first substrate was etched for 300 minutes.

### EXAMPLE 6

A solar cell was manufactured in the same way as in Example 1 except that the first substrate was etched for 600 minutes.

### COMPARATIVE EXAMPLE 1

A solar cell was manufactured in the same way as in Example 1 except that the first substrate was not etched.

### COMPARATIVE EXAMPLE 2

A solar cell was manufactured in the same way as in Example 1 except that the first substrate was etched for 1200 minutes.

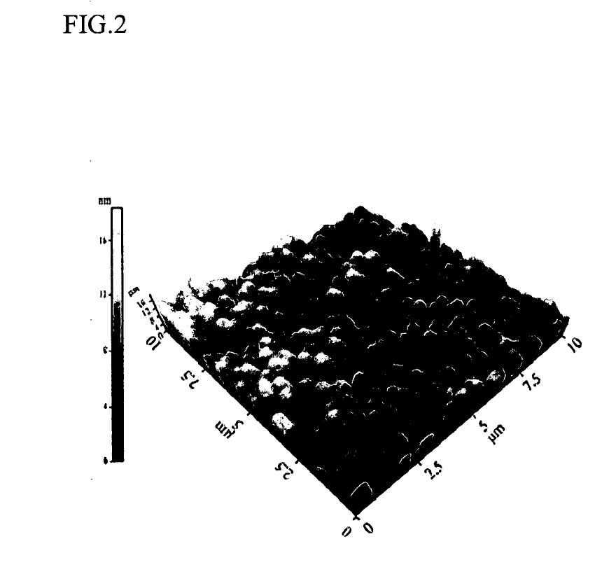

With the solar cell according to the Example 2, an atomic force microscope (AFM) image of the surface of the first electrode with the prominent and depressed portions is presented in FIG. 2. It is known from FIG. 2 that the first electrode formed on the surface of the first substrate with the prominent and depressed portions formed through etching is also provided with prominent and depressed portions. It can be predicted that the contact area between the first electrode and the porous film would be increased due to the prominent and depressed portions. Only an image of the surface of the first electrode of the solar cell according to Example 2 is shown in FIG. 2, but the same type of result may be expected with the other examples.

For the solar cells according to Examples 1 to 6 and Comparative Examples 1 and 2, the Rms of the surface roughness, open circuit voltage, short circuit current, fill factor, light transmittance, and efficiency are listed in Table 1. The open circuit voltage was evaluated from the voltage-current curve where a light source of 100 mW/cm² was corrected by a Si standard cell, and measured. For clearer understanding, the listing sequence is made in accordance with the dimensions of the Rms of the surface roughness.

TABLE 1

| | | Open | Short | | Light | |
|---|---|---|---|---|---|---|
| | Rms of | circuit | circuit | | trans- | Effi- |
| | surface | voltage | current | Fill | mittance | ciency |
| | roughness | (V) | (mA) | factor | (%) | (%) |
| Com. | 8 | 0.763 | 6.810 | 0.613 | 82.2 | 3.187 |
| Ex. 1 | | | | | | |
| Ex. 1 | 38 | 0.751 | 7.090 | 0.611 | 82.1 | 3.253 |
| Ex. 2 | 70 | 0.713 | 8.185 | 0.600 | 81.4 | 3.499 |
| Ex. 3 | 180 | 0.724 | 8.214 | 0.595 | 81.3 | 3.538 |
| Ex. 4 | 325 | 0.691 | 8.199 | 0.641 | 80.5 | 3.632 |
| Ex. 5 | 680 | 0.678 | 8.105 | 0.613 | 80.1 | 3.370 |
| Ex. 6 | 1280 | 0.671 | 8.091 | 0.591 | 79.1 | 3.209 |
| Com. | 3200 | 0.614 | 7.610 | 0.577 | 76.5 | 2.700 |
| Ex. 2 | | | | | | |

It is known from Table 1 that the solar cells according to Examples 1 to 6 have very high short circuit currents with fill factors similar to each other, compared to the solar cells according to Comparative Examples 1 and 2. The short circuit currents of the solar cells according to Examples 1 to 6 were higher than those of the solar cells according to Comparative Examples 1 and 2, and this was presumed to be due to the increase in contact area between the porous film and the first electrode. It turned out that the solar cells according to Examples 1 to 6 had excellent efficiency due to the high short circuit current thereof, compared to the solar cells according to Comparative Examples 1 and 2.

As the Rms of the surface roughness increased, the light transmittance deteriorated. At an Rms of the surface roughness of 3200, according to the solar cell of Comparative Example 2, the decrease in efficiency due to the deterioration in light transmittance was greater than the increase in efficiency due to the enhancement in short circuit current based upon the increased contact area, and hence, the overall efficiency was lower.

As described above, with the solar cell according to aspects of the present invention, a contact area enlargement region is formed at the first electrode at the interface with the light absorption layer, thereby increasing and enhancing the contact characteristics of the light absorption layer and the first electrode and increasing the contact area therebetween. Accordingly, the mobility and migration speed of the excited electrons are improved so that the short circuit current intensity is increased, and the photoelectric conversion efficiency of the solar cell is enhanced.

It is explained in relation to the embodiments described herein that prominent and depressed portions are formed as a contact area enhancement region, but the present invention is not limited thereto. That is, various structural components may be provided to increase the contact area between the first electrode and the porous film, and these alternatives also belong to the scope of the present invention.

It is explained above that a dye-sensitized solar cell is exemplified as a solar cell, but the present invention is not limited thereto. That is, the inventive structure may be applied to other types of solar cells. That is, other types of solar cells having an electrode and a light absorption layer may have an increased contact area between the electrode and the light absorption layer and such other solar cells are also within the scope of the present invention.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A solar cell comprising:
a substrate;
an electrode formed on the substrate; and
a light absorption layer formed on the electrode,
wherein a contact area enlargement region is formed between the electrode and the light absorption layer.

2. The solar cell of claim 1, wherein the contact area enlargement region includes prominent and depressed portions.

3. The solar cell of claim 1, wherein the contact area enlargement region is formed by forming prominent and depressed portions on the substrate, and forming the electrode on the substrate such that the electrode conforms to the prominent and depressed portions of the substrate and forming the light absorption layer on the electrode.

4. The solar cell of claim 2, wherein the prominent and depressed portions are formed in the shape of steps, meshes, scratches, scars or beds.

5. The solar cell of claim 1, wherein the surface roughness of the electrode has a root mean square of 10 nm-3000 nm.

6. The solar cell of claim 1, wherein the surface roughness of the substrate has a root mean square of 10 nm-3000 nm, as measured without the electrode being formed thereon.

7. The solar cell of claim 1, wherein the contact area enlargement region between the electrode and the light absorption layer provides an enhanced interface that facilitates movement of electrons from the light absorption layer to the electrode.

8. A solar cell comprising:
first and second substrates facing each other;
a first electrode formed on the first substrate;
a light absorption layer formed on the first electrode; and
a second electrode formed on the second substrate,
wherein the surface roughness of the first electrode is greater than the surface roughness of the second electrode.

9. The solar cell of claim 8, wherein the surface roughness of the first electrode has a root mean square that is greater than the root mean square of the surface roughness of the second electrode.

10. The solar cell of claim 9, wherein the surface roughness of the first electrode has a root mean square of 10 nm-3000 nm.

11. The solar cell of claim 9, wherein the roughness of the surface of the first substrate with the first electrode has a root mean square of 10 nm-3000 nm.

12. A method of manufacturing a solar cell, the method comprising:
forming an electrode with a contact area enlargement region; and
forming a light absorption layer on the electrode.

13. The method of claim 12, wherein the forming an electrode with a contact area enlargement region comprises forming the electrode on a substrate that has prominent and depressed portions.

14. The method of claim 13, wherein the prominent and depressed portions of the substrate are formed through mechanical etching or chemical etching.

15. The method of claim 13, wherein the prominent and depressed portions of the substrate are formed by sandblasting, scratching, or plasma etching.

16. The method of claim 13, wherein the prominent and depressed portions of the substrate are formed by chemical etching performed with a solution selected from the group consisting of nitric acid, hydrochloric acid, hydrofluoric acid, and a mixture thereof.

17. A method of manufacturing a substrate/electrode/light absorption layer assembly of a solar cell comprising:
etching a substrate through mechanical or chemical etching to form prominent and depressed portions on a surface thereof;
forming an electrode on the surface of the substrate such that a surface of the electrode has prominent and depressed portions conforming to the prominent and depressed portions of the surface of the substrate; and
forming a light absorption layer on the electrode.

18. The method of claim 17, wherein the prominent and depressed portions of the substrate are formed by a mechanical etching method selected from the group consisting of sandblasting, scratching, and plasma etching.

19. The method of claim 17, wherein the prominent and depressed portions of the substrate are formed by chemical etching performed with a solution selected from the group consisting of nitric acid, hydrochloric acid, hydrofluoric acid, and a mixture thereof.

20. A method of manufacturing an electrode/light absorption layer assembly of a solar cell comprising:
forming an electrode on a surface of a substrate and controlling processing conditions of the forming such that a root mean square of roughness of a surface of the electrode is 10 nm-3000 nm; and
forming a light absorption layer on the electrode.

21. The method of manufacturing an electrode light absorption layer assembly of a solar cell of claim 20, wherein the substrate before the electrode is formed thereon has a smooth surface.

22. A method of manufacturing a solar cell, the method comprising:
forming a first electrode with a contact area enlargement region;
forming a light absorption layer on the electrode, and
forming a second electrode, wherein the surface roughness of the first electrode is greater than the surface roughness of the second electrode.
